(19) United States
(12) Patent Application Publication
(10) Pub. No.: US 2017/0003568 A1
(43) Pub. Date: Jan. 5, 2017

(54) DISPLAY UNIT AND ELECTRONIC APPARATUS

(71) Applicant: SONY CORPORATION, Tokyo (JP)

(72) Inventors: SHOTA NISHI, KANAGAWA (JP); MASATO SUZUKI, KANAGAWA (JP); SATOSHI KUMON, TOKYO (JP); TOMOMI YUKUMOTO, CHIBA (JP)

(21) Appl. No.: 15/113,155

(22) PCT Filed: Dec. 11, 2014
(86) PCT No.: PCT/JP2014/082788

§ 371 Date: Jul. 21, 2016

(30) Foreign Application Priority Data
Jan. 30, 2014 (JP) 2014-016028

(51) Int. Cl. G02F 1/167; H01L 51/52

(52) U.S. Cl. CPC G02F 1/167; H01L 51/5253; H01L 51/524; G02F 2001/1676; G02F 1/133305

(57) ABSTRACT

The invention provides a display unit having a drive substrate (11) having a display region and a circuit forming region; a drive device (15) provided at the circuit forming region on the drive substrate (11); a functional film (14) provided to cover the display region and to be opposed to a part of the circuit forming region; and a protective resin layer (17) provided in contact with the drive device.

The display unit of the invention is allowed to prevent damage of connections between the drive device and wiring, and to carry out the detachment while keeping good conditions in a process of detaching the drive substrate from a support substrate.

### TECHNICAL FIELD

The technology relates to a display unit having a drive device such as an IC (Integrated Circuit) on a substrate, and an electronic apparatus that includes such a display unit.

### BACKGROUND ART

In recent years, the demand for a foldable display unit, what is called a flexible display has been growing. The flexible display has a display layer and an opposite substrate at a display region on a flexible substrate. A circuit forming region is provided at the outside of the display region. This circuit forming region may be provided with, for example, a drive device such as an IC for driving of the display layer (for example, see PTL 1 and PTL 2). This drive device is electrically connected with wiring on the flexible substrate.

### CITATION LIST

### Patent Literature

[PTL 1] Japanese Unexamined Patent Application Publication No. 2011-34066

[PTL 2] Japanese Unexamined Patent Application Publication No. 2011-128481

### SUMMARY OF INVENTION

In such a flexible display, it is desired to protect the periphery of a drive device and prevent damage in the vicinity of the drive device that may be caused by folding operation, for example.

Accordingly, it is desirable to provide a display unit that reduces occurrence of damage in the vicinity of a drive device, and an electronic apparatus that includes such a display unit.

A first display unit according to an embodiment of the technology includes: a drive substrate having a display region and a circuit forming region; a drive device provided at the circuit forming region on the drive substrate; a functional film provided to cover the display region and to be opposed to a part of the circuit forming region; and a protective resin layer provided in contact with the drive device.

A first electronic apparatus according to an embodiment of the technology includes the first display unit according to the embodiment of the technology.

A second display unit according to an embodiment of the technology includes: a drive substrate having a display region and a circuit forming region; a drive device provided at the circuit forming region on the drive substrate; and a functional film having a thickness equal to or larger than a thickness of the drive substrate, and provided to cover the display region and to be opposed to a part of the circuit forming region.

A second electronic apparatus according to an embodiment of the technology includes the second display unit according to the embodiment of the technology.

In the first and second display units or the first and second electronic apparatuses according to the respective embodiments of the technology, the functional film is opposed to a part of the circuit forming region, and therefore a difference between the strength of a region in the vicinity of the drive device and the strength on the display region is reduced as compared with a case where the functional film is provided only at the display region.

According to the first and second display units and the first and second electronic apparatuses according to the respective embodiments of the technology, a difference between the strength of the region in the vicinity of the drive device and the strength on the display region is reduced, and therefore it is possible to prevent an external force from being locally applied to the region in the vicinity of the drive device. Thus, it is possible to reduce occurrence of damage in the vicinity of the drive device. Note that effects described here are non-limiting. Effects achieved by the technology may be one or more of effects described in the disclosure.

### BRIEF DESCRIPTION OF DRAWINGS

FIG. 1 is a perspective view of a configuration of a display unit according to a first embodiment of the technology.

FIG. 2 is a cross-sectional view of a partial configuration of a cross-sectional surface along II-II line illustrated in FIG. 1.

FIG. 3 is a cross-sectional view of a partial configuration of a cross-sectional surface along III-Ill line illustrated in FIG. 1.

FIG. 4 is a plan view of an overall configuration of the display unit illustrated in FIG. 1.

FIG. 5 is a plan view of a configuration of a functional film illustrated in FIG. 1.

FIG. 6A is a perspective view of a process in a method of manufacturing the display unit illustrated in FIG. 1.

FIG. 6B is a perspective view of a process in a method of manufacturing the functional film illustrated in FIG. 1.

FIG. 6C is a perspective view of a process following on the process illustrated in FIG. 6A.

FIG. 7A is a perspective view of a process following on the process illustrated in FIG. 6C.

FIG. 7B is a perspective view of a process following on the process illustrated in FIG. 7A.

FIG. 7C is a perspective view of a process following on the process illustrated in FIG. 7B.

FIG. 8 is a perspective view of a configuration of a display unit according to a comparative example.

FIG. 9 is a plan view of a configuration example 1 of a functional film of a display unit according to a modification example.

FIG. 10 is a plan view of a configuration example 2 of the functional film illustrated in FIG. 9.

FIG. 11 is a plan view of a configuration example 3 of the functional film illustrated in FIG. 9.

FIG. 12 is a schematic plan view of a configuration example 4 of the functional film illustrated in FIG. 9.

FIG. 13 is a perspective view of a configuration of a display unit according to a second embodiment of the technology.

FIG. 14 is a cross-sectional view of a partial configuration of a cross-sectional surface along IV-IV line illustrated in FIG. 13.

FIG. 15 is a cross-sectional view of a partial configuration of a cross-sectional surface along V-V line illustrated in FIG. 1.

FIG. 16A is a perspective view of an external appearance of an application example 1 of the display unit illustrated in any of FIG. 1 and other drawings.

FIG. 16B is a perspective view of another example of an external appearance of the application example 1 illustrated in FIG. 16A.

FIG. 17 is a perspective view of an external appearance of an application example 2.

FIG. 18 is a perspective view of an external appearance of an application example 3.

FIG. 19A is a perspective view of an external appearance viewed from the front side of an application example 4.

FIG. 19B is a perspective view of an external appearance viewed from the backside of the application example 4.

FIG. 20 is a perspective view of an external appearance of an application example 5.

FIG. 21 is a perspective view of an external appearance of an application example 6.

FIG. 22A is an external view of an application example 7 in a closed state.

FIG. 22B is an external view of the application example 7 in an open state.

FIG. 23 is a diagram of a magnitude of a force applied to a region in the vicinity of a drive device in the process illustrated in FIG. 7C.

### EMBODIMENTS FOR CARRYING OUT THE INVENTION

Hereinafter, some embodiments of the technology will be described in detail with reference to the drawings. It is to be noted that description will be given in the following order.

### 1. First Embodiment

Display unit: an example where a display unit has a protective resin layer

### 2. Modification Example

An example where a functional film has an aperture

### 3. Second Embodiment

Display unit: an example where a thickness of a functional film is equal to or larger than a thickness of a drive substrate

### 4. Application Examples

### 1. First Embodiment

### Overall Configuration of Display Unit

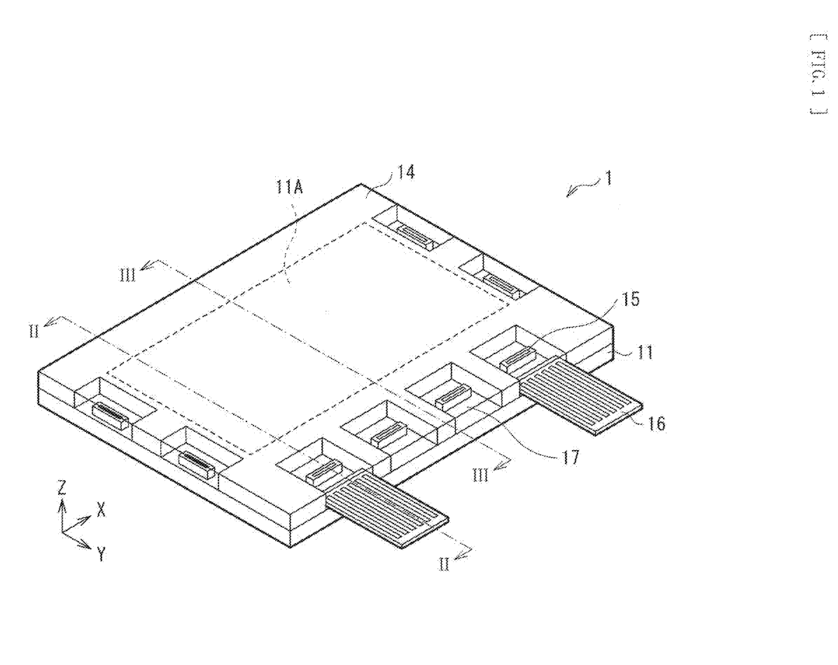

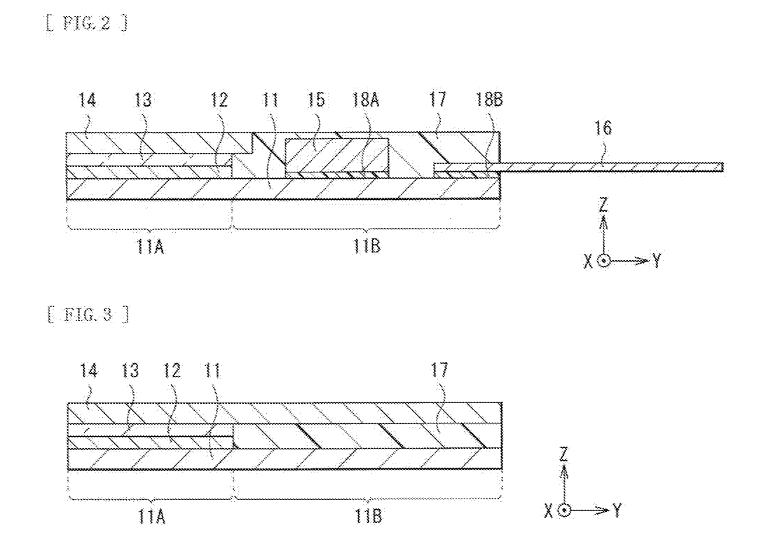

FIG. 1 is a perspective view of a configuration of a display unit (display unit 1) according to a first embodiment of the technology. FIG. 2 illustrates a part of a cross-sectional configuration along II-II line illustrated in FIG. 1, and FIG. 3 illustrates a part of a cross-sectional configuration along III-Ill line illustrated in FIG. 1. This display unit 1 has a display region 11A at the central portion of a drive substrate 11, and a display layer 12 and an opposite substrate 13 are provided on the display region 11A of the drive substrate 11. A functional film 14 is provided on the opposite substrate 13, and the display region 11A of the drive substrate 11 is covered with the function film 14. The drive substrate 11 has a circuit forming region 11B at the outside of the display region 11A, and a drive device 15 and an FPC (Flexible Printed Circuit) 16 (wiring substrate) are provided on this circuit forming region 11B.

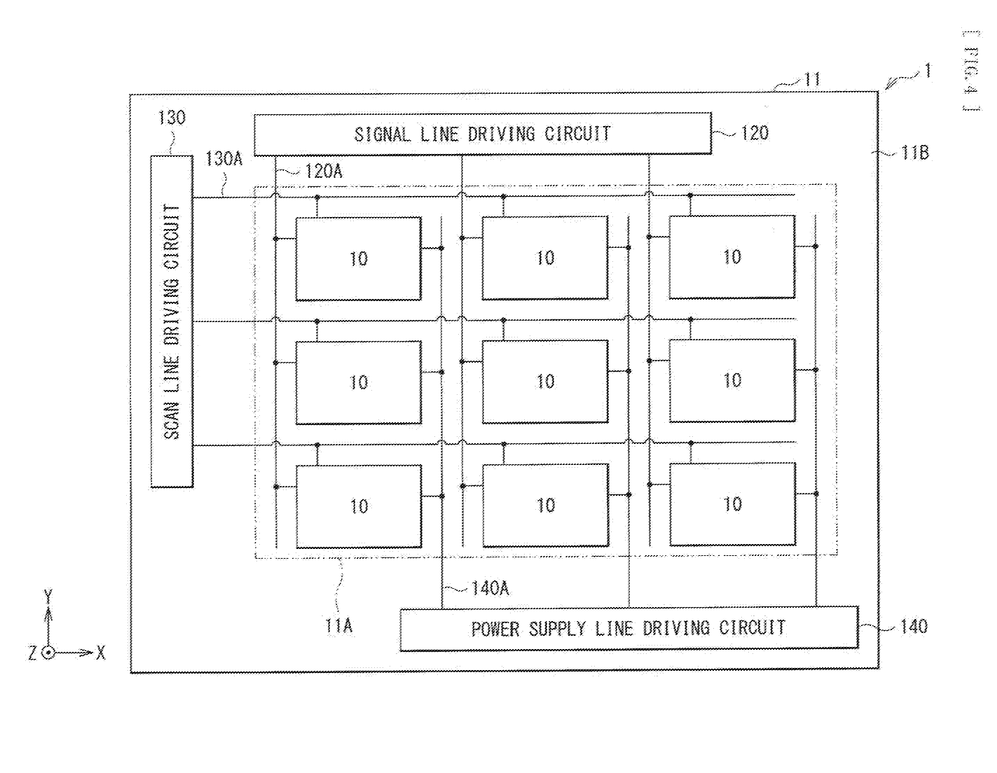

FIG. 4 illustrates an overall configuration of the display unit 1. The display unit 1 is a so-called flexible display, and the drive substrate 11 thereof is configured of a flexible substrate. The display region 11A may take, for example, a rectangular form, and the circuit forming region 11B is provided along three sides surrounding the display region 11A of the drive substrate 11. At the circuit forming region 11B on the drive substrate 11, there may be provided, for example, a signal line driving circuit 120, a scan line driving circuit 130, and a power supply line driving circuit 140 that act as drivers for video picture display. The drive device 15 may function as, for example, the signal line driving circuit 120, the scan line driving circuit 130, and the power supply line driving circuit 140.

The display region 11A is provided with a plurality of pixels 10 that are two-dimensionally arranged in a matrix pattern. A plurality of signal lines 120A (120A1, 120A2, . . . , 120Am, . . . ) and a plurality of power supply lines 140A (140A1, 140An, . . . ) are arranged in columns (in a Y direction) within the display region 11A, and a plurality of scan lines 130A (130A1, 130An, . . . ) are arranged in rows (in an X direction). One pixel 10 is provided at every intersection between each of the signal lines 120A and each of the scan lines 130A. Both ends of each signal line 120A are connected with the signal line driving circuit 120, and both ends of each scan line 130A are connected with the scan line driving circuit 130. Both ends of each power supply line 140A are connected with the power supply line driving circuit 140.

The signal line driving circuit 120 provides, to the pixel 10 selected via the signal line 120A, a signal voltage of an image signal in accordance with luminance information supplied from a signal source (not illustrated). The signal voltage from the signal line driving circuit 120 is applied across both ends of the signal line 120A.

The scan line driving circuit 130 is configured of a shift register that shifts (transfers) start pulses in sequence in synchronization with incoming clock pulses, and any other component. The scan line driving circuit 130 scans the pixels 10 on each row basis in writing an image signal to each of the pixels 10, and provides a scan signal in sequence to each of the scan lines 130A. The scan signal from the scan line driving circuit 130 is provided across both ends of the scan line 130A.

The power supply line driving circuit 140 is configured of a shift register that shifts (transfers) start pulses in sequence in synchronization with incoming clock pulses, and any other component. The power supply line driving circuit 140 provides one of a first potential and a second potential that are different from each other as appropriate to each of the power supply lines 140A across both ends thereof in synchronization with scanning on each column basis that is performed by the signal line driving circuit 120. This may help to select, for example, a conducting state or a non-conducting state of a drive transistor.

### [Configuration of Relevant Parts of Display Unit]

Next, each constituent part of the display unit 1 will be described by referring to FIGS. 1 to 3 once again.

The drive substrate 11 may take, for example, a rectangular form, and may be configured of, for example, but not limited to, a plastic material such as polyimide, polyethylene terephthalate (PET), polyethylene naphthalate (PEN), polymethylmethacrylate (PMMA), polycarbonate (PC), polyether sulfone (PES), polyetheretherketone (PEEK), or aromatic polyester (liquid crystalline polymer). This flexible drive substrate 11 may be configured of an inorganic material such as thin-layer glass or thin-layer ceramics. A thickness of the drive substrate 11 may be, for example, within the range of 10 μm to 100 μm. It may be preferable that the drive substrate 11 be configured of a material with Young's modulus of 10 GPa or less.

A wiring layer (not illustrated) is provided on the drive substrate 11. For example, this wiring layer may have a TFT (Thin-Film Transistor) for each of the pixels 10, and this TFT functions as a switching element for each of the pixels 10. On the wiring layer, along with such TFTs, there may be provided, for example, the signal lines 120A, the scan lines 130A, and the power supply lines 140A (FIG. 4).

To protect the TFT and the display layer 12 from deterioration due to moisture and organic gas, a barrier layer (not illustrated) may be provided between the drive substrate 11 and the wiring layer. The barrier layer may be formed of, for example, AIOXN1-X (where, X is within the range of 0.01 to 0.2) or silicon nitride (Si3N4).

The display layer 12 may be configured of, for example, an electrophoretic type display body. Such an electrophoretic type display body may be provided, for example, between a pixel electrode and a common electrode (not illustrated). For example, the pixel electrode may be provided for each of the pixels 10 on the drive substrate 11, and the common electrodes may be provided all over the opposite substrate 13.

The opposite substrate 13 is opposed to the drive substrate 11 with the display layer 12 interposed between. The opposite substrate 13 has the optical transparency. As a constituent material of the opposite substrate 13, it is possible to use a material similar to that used for the drive substrate 11. By providing a color filter on the opposite substrate 13, the display unit 1 may be configured to carry out color display. An encapsulation resin layer (not illustrated) that surrounds the display layer 12 is provided between the opposite substrate 13 and the drive substrate 11.

The functional film 14 facing the drive substrate 11 with the display layer 12 and the opposite substrate 13 interposed between may be, for example, an optical functional film, and prevents reflected glare of outside light on a display surface. The functional film 14 may be a moisture-proof film to prevent moisture from coming into the display layer 12, or a protective film to reduce the impact from outside.

As a constituent material of the functional film 14, it is possible to use resin materials, such as PET, PEN, PMMA, PC, TAC (triacetylcellulose), PI (polyimide), and fluorine resin. The functional film 14 may be preferably larger than the drive substrate 11 in thickness. A thickness of the functional film 14 may be, for example, within the range of 50 μm to 100 μm.

FIG. 5 illustrates a planar configuration of the functional film 14. The functional film 14 covers the display region 11A of the drive substrate 11, while extending to the circuit forming region 11B. More specifically, in the embodiment, the functional film 14 is opposed to a part of the circuit forming region 11B. As will hereinafter be described in detail, this results in a difference between a strength of a region in the vicinity of the drive device 15 and a strength on the display region 11A of the drive substrate 11 being made smaller as compared with a case where the functional film 14 is provided only at a region facing the display region 11A.

The functional film 14 has a notch portion 14L at a region facing the circuit forming region 11B, and the circuit forming region 11B of the drive substrate 11 is exposed at this notch portion 14L. The drive device 15 is disposed at a position overlapping with this notch portion 14L in planar view (X-Y plane). In other words, a region (non-superposed region) that does not overlap with the functional film 14 is provided at the circuit forming region 11B of the drive substrate 11, and the drive device 15 is provided at the non-superposed region that does not overlap with the functional film 14. By providing the notch portion 14L on the functional film 14, it becomes easy to mount the drive device 15 on the drive substrate 11.

The notch portion 14L of the functional film 14 may take, for example, a quadrangular form. By providing the quadrangular notch portion 14L, three peripheral sides of the drive device 15 are surrounded by the functional film 14 in planar view. A part (one side) of a peripheral region of the drive device 15 is open to the outside of the functional film 14. The notch portion 14L may take, for example, a triangular form in such a manner that two peripheral sides of the drive device 15 are surrounded by the functional film 14 (not illustrated). Alternatively, the notch portion 14L may take an elliptical form in such a manner that the peripheral region of the drive device 15 is surrounded in an arc by the functional film 14 (not illustrated). The notch portion 14L may take any form. For example, the notch portions 14L may be provided at three sides of the rectangular functional film 14. The notch portions 14L may be provided at all sides of the functional film 14, or may be provided at one side or two sides. The arrangement of the notch portions 14L may be adjusted to fit the arrangement of the drive device 15 (circuit forming region 11B).

A protective resin layer 17 is filled into the notch portion 14L of the functional film 14 (FIG. 1 to FIG. 3). This protective resin layer 17 comes in contact with the drive device 15, and covers a region from a top surface (a surface opposite to a surface facing the drive substrate 11) to side surfaces of the drive device 15. More specifically, the protective resin layer 17 is provided around the drive device 15. The protective resin layer 17 may be provided only around the drive device 15; however, the protective resin layer 17 may be preferably provided over the entire region (the notch portions 14L) that is surrounded by the functional film 14 in such a manner that a gap between the functional film 14 and the drive device 15 is filled by the protective resin layer 17.

More preferably, the Young's modulus of the protective resin layer 17 may be nearly equivalent to that of the functional film 14, and may be, for example, within the range of 1 GPa to 5 GPa. For such a protective resin layer 17, it is possible to use a material such as thermosetting resin or photo-curable resin. An example of the photo-curable resin may include ultraviolet curable resin.

Each of the drive device 15 and the FPC 16 that are provided at the circuit forming region 11B on the drive substrate 11 are electrically connected with wiring (not illustrated) on the drive substrate 11. The drive device 15 may be, for example, a driver IC, and is electrically connected with the TFT at the display region 11A via wiring on the drive substrate 11. By providing the driver IC (drive device 15) directly on the drive substrate 11, it is possible to reduce cost as compared with COF (Chip On Film) mounting. In the FPC 16, a wiring pattern is provided on one side or both sides of a flexible film base material. This FPC 16 is provided in such a manner that a part thereof is opposed to the drive substrate 11, and is electrically connected with the drive device 15 via wiring (not illustrated) on the drive substrate 11. For example, the FPC 16 may be provided at a position overlapping with the notch portions 14L of the functional film 14 in planar view at the circuit forming region 11B of the drive substrate 11, and a part of the FPC 16 in opposition to the drive substrate 11 is covered by the protective resin layer 17 together with the drive device 15. Other part of the FPC 16 is exposed to the outside of the drive substrate 11, and may be connected with, for example, a relay substrate (not illustrated). An adhesive layer 18A is provided between the drive device 15 and wiring, and an adhesive layer 18B is provided between the FPC 16 and wiring. Each of the adhesive layers 18A and 18B may be configured of, for example, an ACF (Anisotropic Conductive Film).

### [Method of Manufacturing Display Unit]

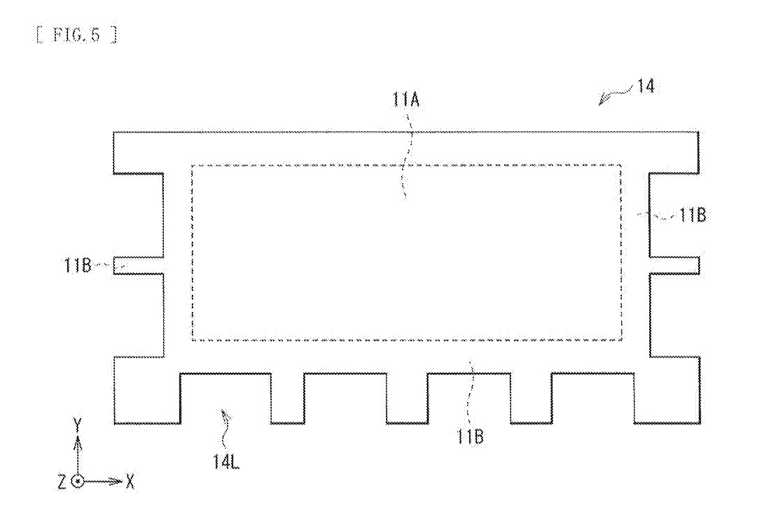

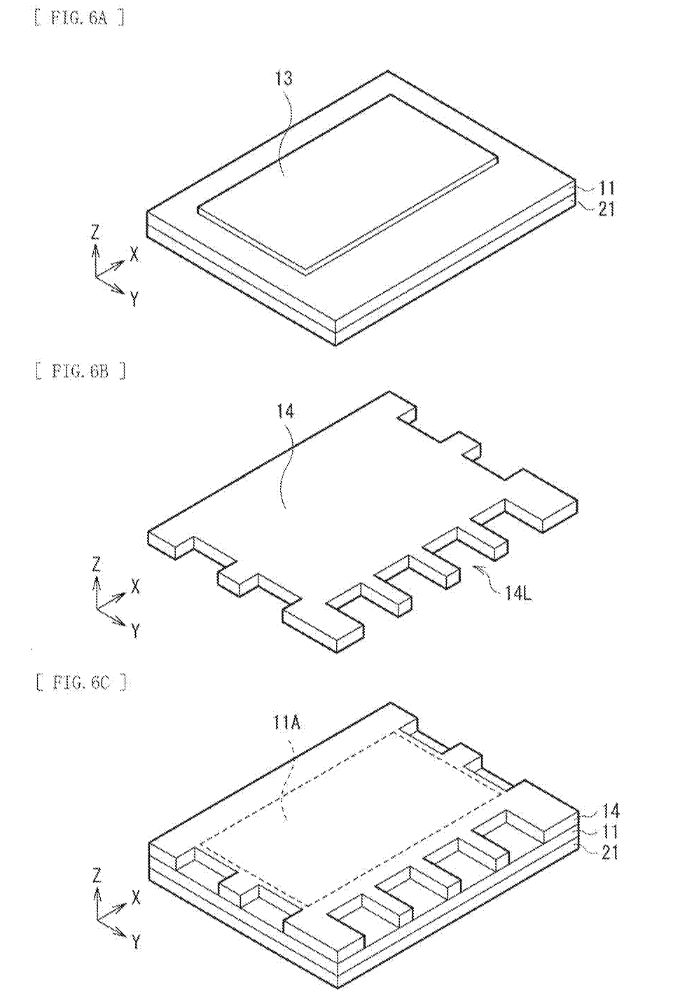

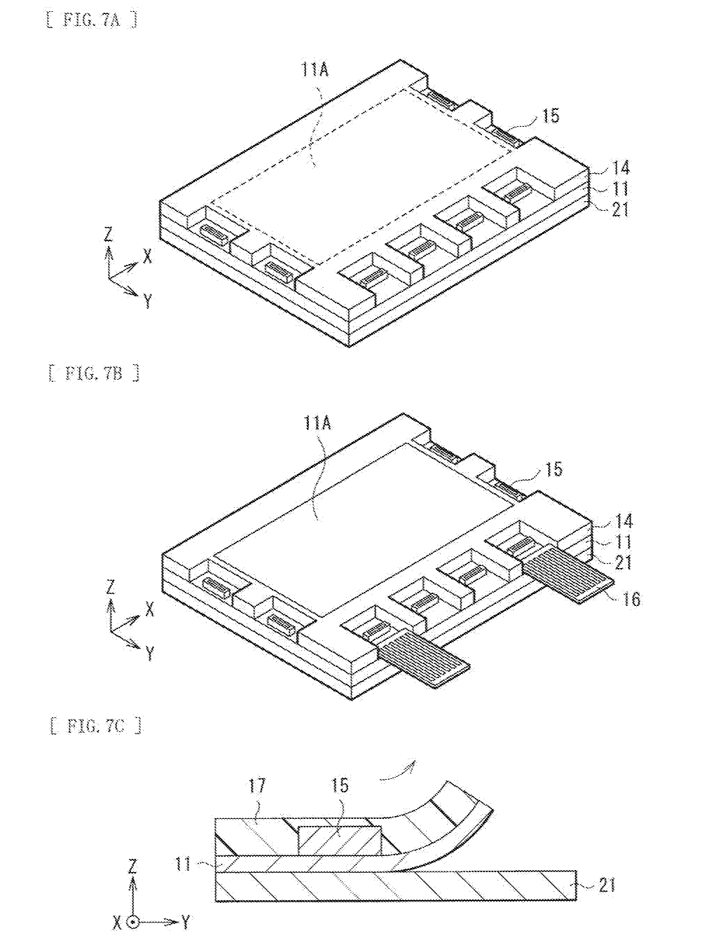

This display unit 1 may be allowed to be manufactured in such a method as described below (FIG. 6A to FIG. 7C).

First, the drive substrate 11 is fixed on a support substrate 21, and thereafter a wiring layer (not illustrated) is formed on the drive substrate 11. As the support substrate 21, a glass substrate with a thickness, for example, within the range of 0.5 mm to 1 mm may be used. Next, for example, pixel electrodes and the electrophoretic type display bodies may be provided at the display region 11A of the drive substrate 11, and the opposite substrate 13 with common electrode formed thereon is bonded with the resulting drive substrate 11. In this method, the display layer 12 and the opposite substrate 13 are formed at the display region 11A of the drive substrate 11 (FIG. 6A).

In contrast, as illustrated in FIG. 6B, by using, for example, but not limited to, Thomson mold, the functional film 14 having the notch portions 14L is formed. This resin film 14 is opposed to the drive substrate 11 on which the display layer 12 and the opposite substrate 13 are provided to bond together (FIG. 6C).

Subsequently, by the use of the adhesive layer 18A, the drive device 15 is electrically connected with wiring (not illustrated) that is provided at a region overlapping with the notch portions 14L of the functional film 14 at the circuit forming region 11B of the drive substrate 11 (FIG. 7A). By providing the notch portions 14L on the functional film 14, the drive device 15 is allowed to be mounted on the drive substrate 11 after bonding the functional film 14 with the drive substrate 11. Thereafter, as illustrated in FIG. 7B, by the use of the adhesive layer 18B, the FPC 16 is electrically connected with wiring (not illustrated) that is provided at the circuit forming region 11B of the drive substrate 11.

After the FPC 16 is provided, a resin material is filled into the notch portions 14L of the functional film 14, and such a resin material is hardened to form the protective resin layer 17. Afterwards, as illustrated in FIG. 7C, by the use of, for example, but not limited to, a roller, the drive substrate 11 is mechanically detached from the support substrate 21. By the use of, for example, but not limited to, laser irradiation, the drive substrate 11 may be detached from the support substrate 21. After detachment of the drive substrate 11 from the support substrate 21, the drive device 15, the FPC 16, and the protective resin layer 17 may be provided alternatively. With the processes described thus far, the display unit 1 as illustrated in FIG. 1 to FIG. 3 is brought to perfection.

### [Operation of Display Unit]

In the display unit 1, when an external signal is provided to the drive device 15 as an input via the FPC 16, a drive signal is provided from the drive device 15 to each of the pixels 10 to display an image on the opposite substrate 13.

Here, the functional film 14 covering the display region 11A is also opposed to a part of the circuit forming region 11B of the drive substrate 11, and therefore a difference between the strength of the region in the vicinity of the drive device 15 and the strength on the display region 11A is made smaller as compared with a case where the functional film 14 is provided to be opposed to only the display region 11A. This will be described hereinafter.

FIG. 8 illustrates a configuration of a display unit (display unit 100) according to a comparative example. A functional film (functional film 114) of this display unit 100 only covers the display region 11A of the drive substrate 11, and is not provided at the circuit forming region 11B. That is, the circuit forming region 11B of the drive substrate 11 is exposed from the functional film 114 over the entire region. In such a display unit 100, the hardness on the display region 11A where the functional film 114 is superposed and the hardness on the circuit forming region 11B without the functional film 114 are significantly different from each other, and thus the strength is also significantly different from each other accordingly. Therefore, a force applied from the outside due to folding operation or any other operation may be exerted locally on the flexible (low-strength) circuit forming region 11B, which could pose risk of damaging connections of the drive device 15 and wiring, or any other part.

Further, the display unit 100 may be manufactured through, for example, a process where the drive substrate 11 is detached from a support substrate (for example, the support substrate 21 in FIG. 6A) (see FIG. 7C). At this time, a force may be applied locally to the circuit forming region 11B of the drive substrate 11, which could pose risk of damaging connections of the drive device 15 and wiring, or any other part. The drive device 15 may be provided after detachment of the drive substrate from the support substrate. However, also in this case, when a force is applied intensively to the circuit forming region 11B of the drive substrate 11, for example, change in dimension and warpage of the drive substrate 11 may occur. Therefore, this makes it difficult to mount the drive device 15.

The circuit forming region 11B of the drive substrate 11 may be also allowed to be strengthened in a method of, for example, folding back a peripheral border (the circuit forming region 11B) of the drive substrate 11 to increase the thickness (see the PTL 1). In this case, however, the peripheral border of the drive substrate 11 becomes larger in thickness than a display region at the center of the drive substrate 11, which may make it difficult to function as a flexible display. Moreover, the area of the drive substrate 11 becomes larger in comparison with the display unit 100, which results in a decrease in the number of chamfers of a panel and an increase in cost.

A method of enhancing the strength of the circuit forming region 11B by extending an opposite substrate (for example, the opposite substrate 13 in FIG. 2) as far as the circuit forming region 11B may be also considered (see the PTL 2). However, a color filter and other components are formed on the opposite substrate, and thus in most cases, the opposite substrate may be formed using more expensive materials as compared with a functional film. Therefore, an increase in the area of the opposite substrate leads to an increase in cost. Further, an increase in the area of the opposite substrate results in an increase in the formation area of an encapsulation resin layer surrounding a display layer (for example, the display layer 12 in FIG. 2). A constituent material of this encapsulation resin layer is expensive, and thus an increase in the formation area of the encapsulation resin layer also leads to an increase in cost.

In contrast, in the display unit 1, the functional film 14 is provided to cover the display region 11A of the drive substrate 11 and to be opposed to a part of the circuit forming region 11B, and thus a difference between the strength on the circuit forming region 11B and the strength on the display region 11A is made smaller as compared with the display unit 100. Therefore, a difference between the strength on the circuit forming region 11B and the strength on the display region 11A is reduced, and a force applied from the outside due to folding operation or any other operation may disperse more easily onto the display region 11A and the circuit forming region 11B. This ensures that the connections of the drive device 15 and wiring, and other parts are maintained in a good condition.

Further, also in a process of detaching the drive substrate 11 from the support substrate 21 (FIG. 7C), a difference between the strength of the circuit forming region 11B and the strength of the display region 11A is small, and thus an influence on the region in the vicinity of the drive device 15 is reduced. Even when the drive device 15 is provided after detachment of the drive substrate 11 from the support substrate 21, a state of the circuit forming region 11B of the drive substrate 11 is maintained as it is, and it is unlikely that, for example, change in dimension and warpage will occur. Therefore, after detachment of the drive substrate 11 from the support substrate 21, it is possible to mount the drive device 15 with ease on the drive substrate 11.

Moreover, the functional film 14 is provided over a region from the display region 11A of the drive substrate 11 to the circuit forming region 11B, and thus a thickness of the central part (the display region 11A) and a thickness of the peripheral part (the circuit forming region 11B) become substantially equivalent to each other in the display unit 1. This makes it possible to optimally use the display unit 1 for a flexible display. Further, it is possible to make the number of chamfers of a panel equivalent to that in the case of the display unit 100, resulting in an increase in cost being reduced.

In addition, it is possible to use an inexpensive material for the functional film 14, which makes it possible to reduce an increase in cost as compared with a case where the area of the opposite substrate 13 is increased.

As described above, in the display unit 1 according to the embodiment, a difference between the strength of the region in the vicinity of the drive device 15 and the strength on the display region 11A is reduced, and thus it is possible to prevent an external force from being applied locally to the region in the vicinity of the drive device 15. This makes it possible to reduce occurrence of damage in the vicinity of the drive device 15 including damage of connections between the drive device 15 and wiring. This helps to improve the yield and reliability of the display unit 1. Further, also by making the functional film 14 larger than the drive substrate 11 in thickness, a difference between the strength of the region in the vicinity of the drive device 15 and the strength on the display region 11A is made smaller.

Additionally, by providing the protective resin layer 17 in contact with the drive device 15, a difference between the strength of the region in the vicinity of the drive device 15 and the strength of the display region 11A is made smaller. It may be preferable that the Young's modulus of the protective resin layer 17 be close to that of a constituent material for the functional film 14. This ensures that a difference between the strength of the region in the vicinity of the drive device 15 and the strength of the display region 11A is made smaller.

Further, the notch portions 14L are provided at a region facing the circuit forming region 11B on the functional film 14, and thus it is possible to mount the drive device 15 with ease on the drive substrate 11 even after the functional film 14 is bonded with the drive substrate 11.

Hereinafter, a description is provided on a modification example of the above-described first embodiment and another embodiment. Any component parts essentially same as those in the above-described first embodiment are denoted with the same reference numerals, and the related descriptions are omitted as appropriate.

### Modification Example

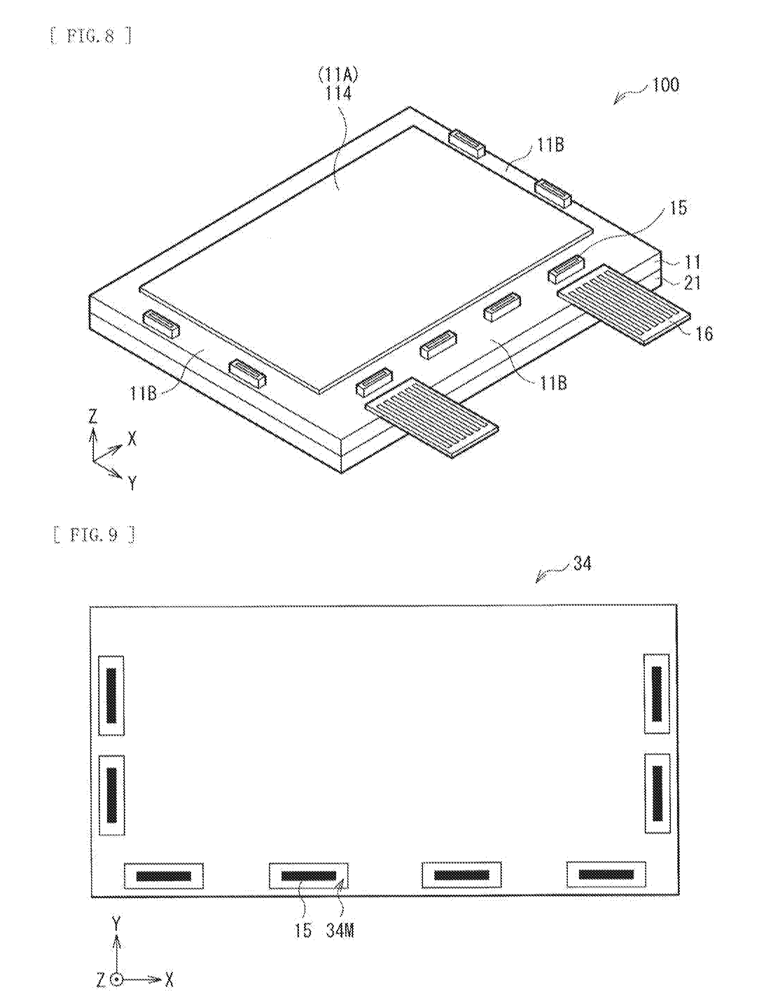

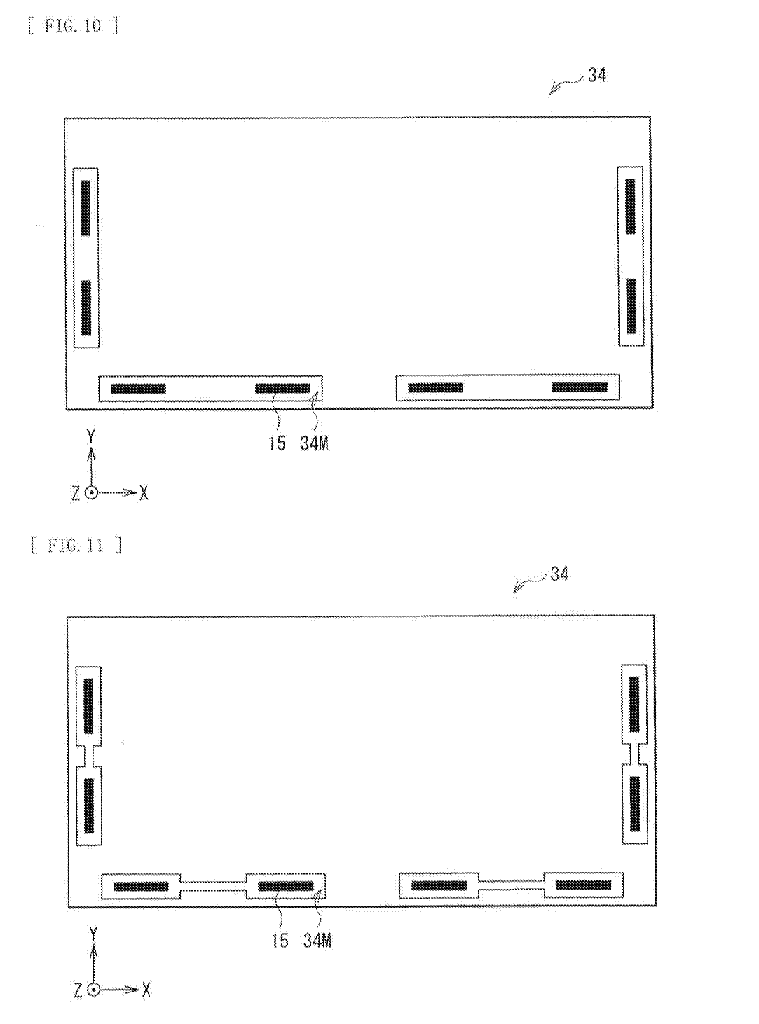

Each of FIG. 9 to FIG. 12 illustrates a modification example of the functional film of the display unit 1 (functional film 34). This functional film 34 has apertures (apertures 34M). With the exception of this point, the functional film 34 has a configuration similar to that of the above-described functional film 14, and the function and effects thereof are also similar to those of the functional film 14.

The apertures 34M of the functional film 34 are provided at an opposite region of the circuit forming region 11B (FIG. 2). The drive device 15 is disposed at a position overlapping with the aperture 34M of the functional film 34 in planar view.

As illustrated in FIG. 9, the aperture 34M may take, for example, a quadrangular form, and one of the drive devices 15 is disposed to overlap with one of the apertures 34M. At this time, four peripheral sides of the drive device 15 are all surrounded by the functional film 34 The protective resin layer 17 (FIG. 2) is filled into the aperture 34M of the functional film 34, and the protective resin layer 17 is in contact with the drive device 15.

As illustrated in FIG. 10, a plurality of drive devices 15 may be disposed at one aperture 34M. FIG. 10 illustrates a case where two drive devices 15 are provided at one aperture 34M; however, three or more drive devices 15 may be provided at one aperture 34M.

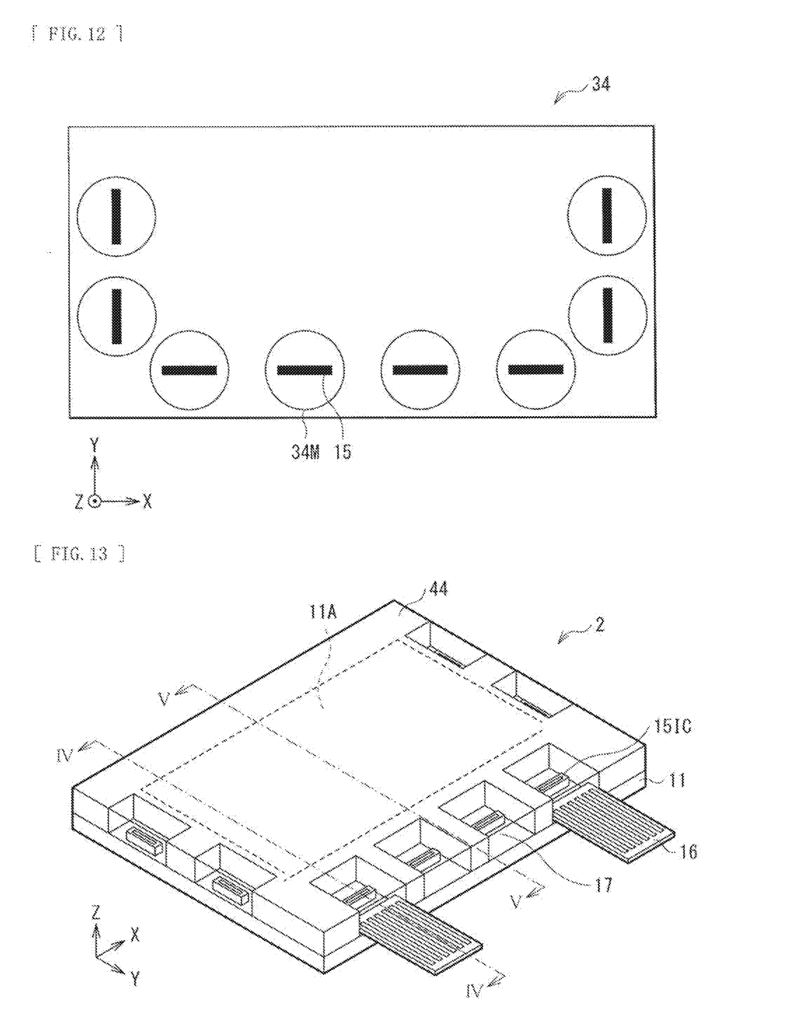

As illustrated in FIG. 11, a width of the aperture 34M may be varied in one aperture 34M. When the width of the aperture 34M is reduced in a region between adjacent two of the drive devices 15 that are provided at one aperture 34M, the area of the aperture 34M surrounding the drive device 15 is increased as compared with a case where the entire width of the aperture 34M are the same (FIG. 10). As a result, a difference between the strength of the region in the vicinity of the drive device 15 and the strength of the display region 11A is made smaller.

The aperture 34M may take any form, and may take, for example, a circular form (FIG. 12).

### Second Embodiment

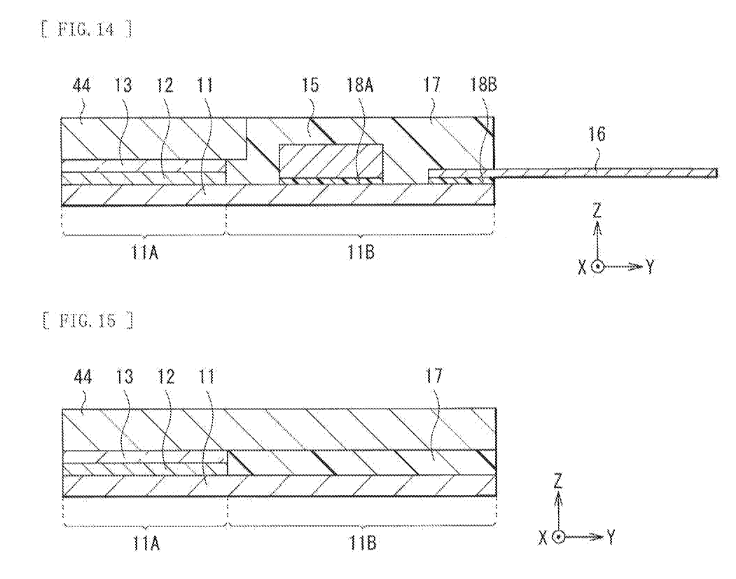

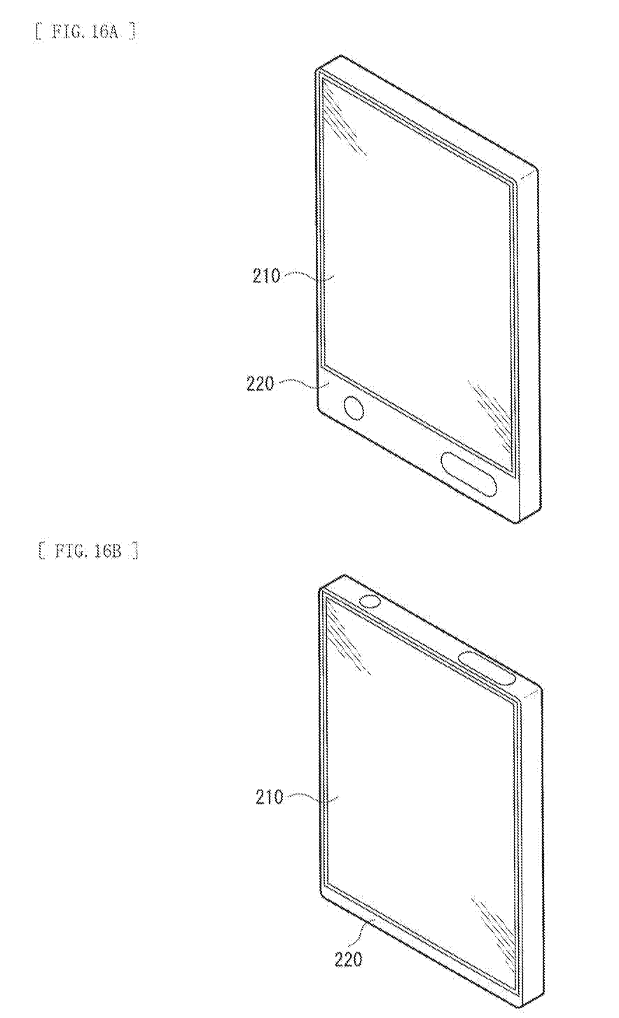

FIG. 13 is a perspective view of a configuration of a display unit (display unit 2) according to a second embodiment of the technology. FIG. 14 illustrates a part of a cross-sectional configuration along IV-IV line illustrated in FIG. 13, and FIG. 15 illustrates a part of a cross-sectional configuration along V-V line illustrated in FIG. 13. A functional film (functional film 44) of the display unit 2 has a thickness equal to or larger than a thickness of the drive substrate 11. With the exception of this point, the display unit 2 has a configuration similar to that of the display unit 1, and the function and effects thereof are also similar to those of the display unit 1.

As with the functional film 14 (FIG. 1 and other drawings) of the above-described display unit 1, the functional film 44 may be, for example, but not limited to, an optical functional film, a moisture-proof film, or a protective film, and covers the display region 11A of the drive substrate 11. A thickness of the functional film 44 is equal to or larger than the thickness of the drive substrate 11, and may be preferably be larger than the thickness of the drive substrate 11. The thickness of the functional film 44 may be, for example, one to four times as large as the thickness of the drive substrate 11, and may be specifically within the range of 50 μm to 200 μm. This functional film 44 is provided to be opposed to a part of the circuit forming region 11B of the drive substrate 11. As with the display unit 1, this ensures that a difference between the strength of the region in the vicinity of the drive device 15 and the strength on the display region 11A is made smaller. As a result, it is possible to prevent an external force from being applied locally to the region in the vicinity of the drive device 15.

As with the functional film 14, the functional film 44 is provided with notch portions (the notch portions 14L in FIG. 5), and the drive device 15 is disposed at a position overlapping with the notch portion of the functional film 14, that is, at a non-superposed region that does not overlap with the functional film 14. Instead of such notch portions, the functional film 44 may be provided with apertures (the apertures 34M in FIG. 9 to FIG. 12). As with the display unit 1, it may be preferable that the protective resin layer 17 be provided at the notch portion or the aperture of the functional film 44, and that the protective resin layer 17 be in contact with the drive device 15.

### APPLICATION EXAMPLES

The above-described display units 1 and 2 are allowed to be mounted on the electronic apparatuses according to the following application examples 1 to 7, for example.

### Application Example 1

Each of FIG. 16A and FIG. 16B illustrates an external appearance of an electronic book to which any of the display units (display units 1 and 2) according to any of the above-described embodiments and modification examples is applied. This electronic book may have, for example, a display section 210 and a non-display section 220, and the display section 210 is configured of any of the display units according to any of the above-described embodiments and modification examples.

### Application Example 2

FIG. 17 illustrates an external appearance of a smartphone to which any of the display units according to any of the above-described embodiments and modification examples is applied. This smartphone may have, for example, a display section 230 and a non-display section 240, and the display section 230 is configured of any of the display units according to any of the above-described embodiments and modification examples.

### Application Example 3

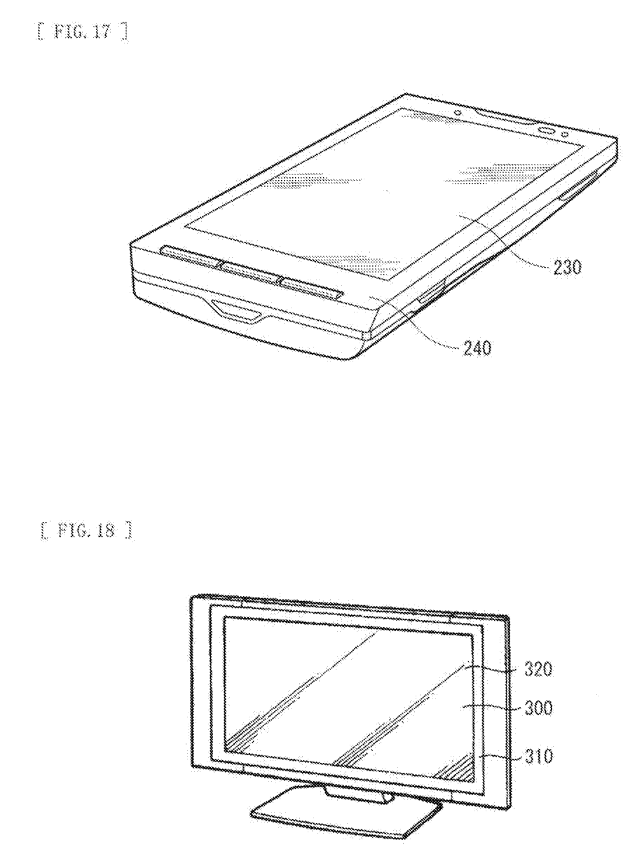

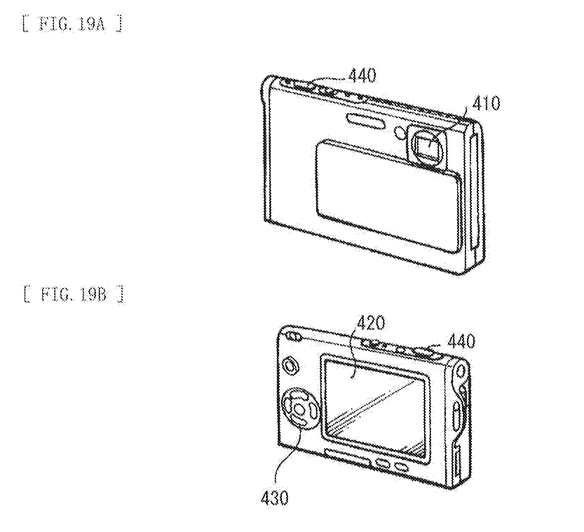

FIG. 18 illustrates an external appearance of a television to which any of the display units according to any of the above-described embodiments and modification examples is applied. This television may have, for example, an image display screen section 300 including a front panel 310 and a filter glass 320, and this image display screen section 300 is configured of any of the display units according to any of the above-described embodiments and modification examples.

### Application Example 4

Each of FIG. 19A and FIG. 19B illustrates an external appearance of a digital camera to which any of the display units according to any of the above-described embodiments and modification examples is applied. This digital camera may have, for example, a light-emitting section 410 for flashing, a display section 420, a menu switch 430, and a shutter button 440, and this display section 420 is configured of any of the display units according to any of the above-described embodiments and modification examples.

### Application Example 5

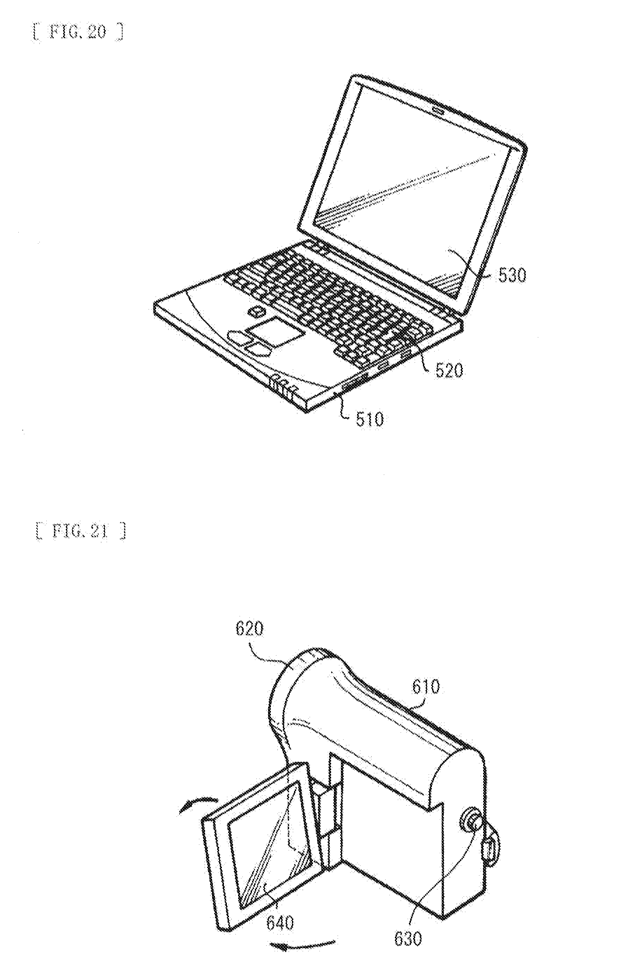

FIG. 20 illustrates an external appearance of a notebook personal computer to which any of the display units according to any of the above-described embodiments and modification examples is applied. This notebook personal computer may have, for example, a main unit 510, a keyboard 520 for operation of entering characters, etc., and a display section 530 for displaying images, and this display section 530 is configured of any of the display units according to any of the above-described embodiments and modification examples.

### Application Example 6

FIG. 21 illustrates an external appearance of a video camera to which any of the display units according to any of the above-described embodiments and modification examples is applied. This video camera may have, for example, a main unit section 610, a lens 620 provided at a front lateral surface of this main unit section 610 and for shooting an image of a subject, a shooting start and stop switch 630, and a display section 640. This display section 640 is configured of any of the display units according to any of the above-described embodiments and modification examples.

### Application Example 7

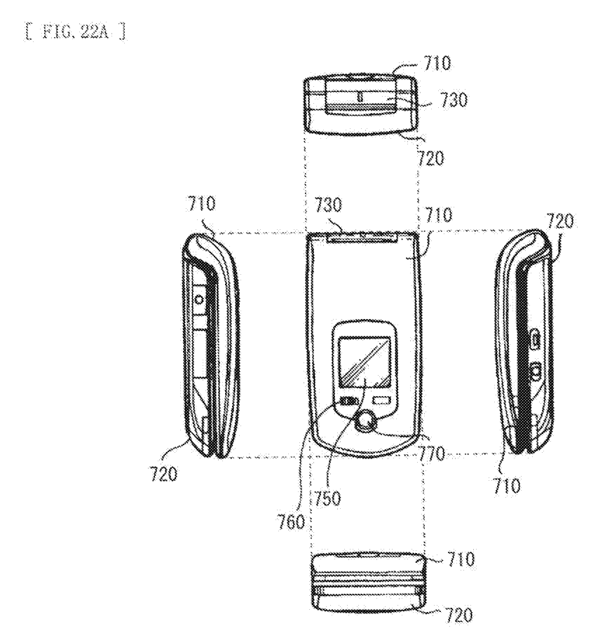

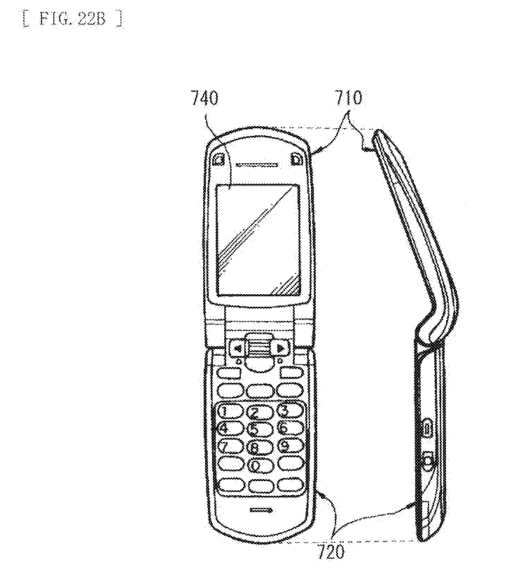

Each of FIG. 22A and FIG. 22B illustrates an external appearance of a mobile phone to which any of the display units according to any of the above-described embodiments and modification examples is applied. For example, this mobile phone may join an upper chassis 710 and a lower chassis 720 by means of a connecting section (hinge section) 730, and may have a display 740, a sub-display 750, a picture light 760, and a camera 770. The display 740 or the sub-display 750 of these component parts is configured of any of the display units according to any of the above-described embodiments and modification examples.

### EXPERIMENTAL EXAMPLES

Hereinafter, a description is provided on specific experimental examples of the technology.

### Experimental Example 1

As described in the above first embodiment, the display unit 1 illustrated in FIG. 1 was produced. First, the drive substrate 11 was fixed to the support substrate 21, and thereafter a wiring layer, the display layer 12, and the opposite substrate 13 were formed on this drive substrate 11. Next, the functional film 14 provided with the notch portions 14L was bonded with the drive substrate 11, and subsequently the drive device 15, the FPC 16, and the protective resin layer 17 were provided on the drive substrate 11. Finally, the drive substrate 11 was detached from the support substrate 21 to produce the display unit 1. The drive substrate 11 used a plastic material with a thickness of 40 μm (Young's modulus of 5 GPa), and the functional film 14 used a PET (Polyethylene Terephthalate) material with a thickness of 125 μm (Young's modulus of 3 GPa to 4 GPa), and further the protective resin layer 17 used a thermosetting resin material (Young's modulus of 3.5 GPa). The protective resin layer 17 was filled into the notch portions 14L of the functional film 14.

### Experimental Example 2

The protective resin layer 17 used a thermosetting resin material (Young's modulus of 0.55 GPa). With the exception of this point, the display unit 1 was produced in a manner similar to the experimental example 1.

### Experimental Example 3

The functional film 14 with a thickness of 250 μm was used. With the exception of this point, the display unit 1 was produced in a manner similar to the experimental example 1.

### Experimental Example 4

The functional film 14 with a thickness of 250 μm was used. With the exception of this point, the display unit 1 was produced in a manner similar to the experimental example 2.

### Experimental Example 5

With the exception that a functional film and a protective resin layer were not provided at a region facing the circuit forming region 11B, the display unit 1 was produced in a manner similar to the experimental example 1.

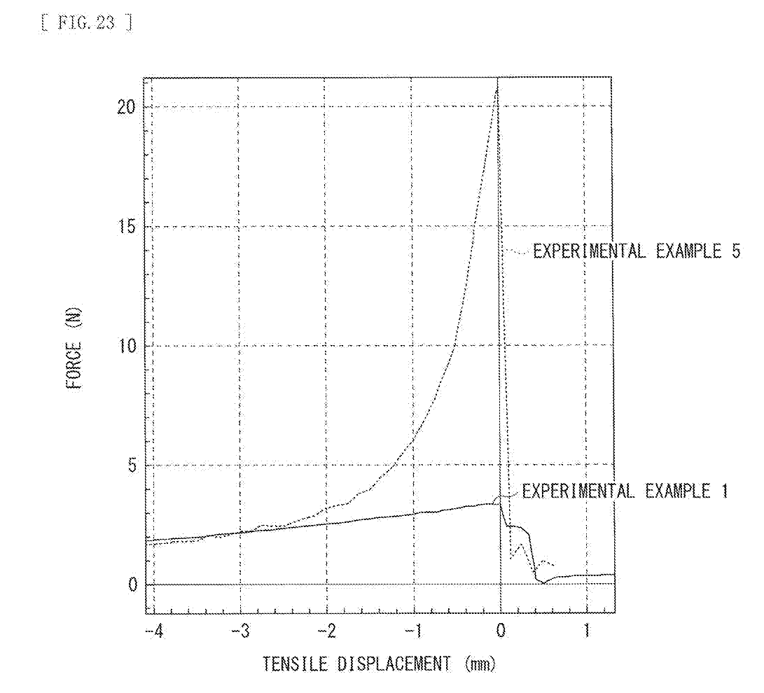

In the experimental examples 1 and 5, in detaching the drive substrate 11 from the support substrate 21, a force applied to the region in the vicinity of the drive device 15 was measured. This result is illustrated in FIG. 23. The force applied to the region in the vicinity of the drive device 15 in a detachment process was measured using a tensile testing machine (IMADA MX2-500N). The speed of the tensile testing machine was set to 10 mm/min.

In the experimental example 1 where the functional film 14 and the protective resin layer 17 were provided at a region facing the circuit forming region 11B, the force applied to the region in the vicinity of the drive device 15 decreased significantly as compared with the experimental example 5.

In the experimental examples 1 to 5, a connection resistance between the drive device 15 and wiring before a process of detaching the drive substrate 11 from the support substrate 21 and such a connection resistance after the detachment process were measured. This result is shown in Table 1. Table 1 denotes a ratio of the connection resistance before the detachment process to the connection resistance after the detachment process (connection resistance before detachment process/connection resistance after detachment process×100) as a resistance rising rate (%).

TABLE 1

| | | | Protective | |
|---|---|---|---|---|
| | | | resin layer | |
| | Functional film | | Young's | |
| Experimental | Young's | | modulus | Resistance |
| examples | modulus (GPa) | Thickness (μm) | (GPa) | rise rate (%) |
| 1 | 3 to 4 | 125 | 3.5 | 1.1 |
| 2 | | | 0.55 | 40 |
| 3 | | 250 | 3.5 | 1.2 |
| 4 | | | 0.55 | 1.8 |
| 5 | — | — | — | 120 |

In the experimental examples 1 to 4 where the functional film 14 and the protective resin layer 17 were provided at the region facing the circuit forming region 11B, an increase in the resistance after detachment was reduced as compared with the experimental example 5. More specifically, such a result shows that damage of connections between the drive device 15 and wiring is prevented, and good conditions are maintained.

Comparison between the experimental example 1 and the experimental example 2 shows that if Young's modulus of the protective resin layer 17 is closer to that of the functional film 14, it is more unlikely that the detachment process will have an influence on the region in the vicinity of the drive device 15.

Comparison between the experimental example 2 and the experimental example 4 shows that when constituent materials for the functional film 14 are the same in Young's modulus, if the thickness of the functional film 14 is larger, it is more unlikely that the detachment process will have an influence on the region in the vicinity of the drive device 15.

The technology is described thus far with reference to some embodiments and modification examples; however, the technology is not limited to the above-described embodiments and modification examples, but various modifications may be made. For example, in the above-described embodiments and modification examples, the description is provided on a case where the display layer 12 is configured of electrophoretic type display body, but the display layer 12 may be configured of, for example, but not limited to, a liquid crystal layer, an organic EL (Electroluminescence) layer, or an inorganic EL layer.

Further, the material and thickness of each layer, the method and conditions of forming each layer are not limited to those described in the above-described embodiments and modification examples, and any other materials and thicknesses, or any other methods and conditions may be used alternatively.

Moreover, in the above-described embodiments and modification examples, the description is provided by taking configurations of the display units 1 and 2 as specific examples; however, any other members may be provided additionally.

It is to be noted that the effects described in the present specification are provided only for illustrative purposes. Therefore, such effects are not limited thereto, and any other effects may be available.

It is to be noted that the technology may have following configurations.

(1) A display unit, comprising:

a drive substrate having a display region and a circuit forming region;

a drive device provided at the circuit forming region on the drive substrate;

a functional film provided to cover the display region and to be opposed to a part of the circuit forming region; and

a protective resin layer provided in contact with the drive device.

(2) The display unit according to (1), wherein the derive device is provided at a non-superposed region that does not overlap with the functional film of the circuit forming region.

(3) The display unit according to (1) or (2), wherein at least a part of a peripheral region of the drive device is surrounded by the functional film in planar view.

(4) The display unit according to (3), wherein the protective resin layer is provided over a region surrounded by the functional film.

(5) The display unit according to any one of (1) to (5), wherein a thickness of the functional film is larger than a thickness of the drive substrate.

(6) The display unit according to any one of (1) to (5), wherein the functional film has a notch portion, and the drive device is provided at a position overlapping with the notch portion in planar view.

(7) The display unit according to any one of (1) to (5), wherein the functional film has an aperture, and the drive device is provided at a position overlapping with the aperture in planar view.

(8) The display unit according to any one of (1) to (7), wherein a display layer and an opposite substrate are provided at the display region on the drive substrate, and the functional film is opposed to the drive substrate with the display layer and the opposite substrate interposed between.

(9) The display unit according to (8), wherein the display layer includes an electrophoretic type display body.

(10) The display unit according to (8), wherein the display layer includes an organic EL layer.

(11) The display unit according to any one of (1) to (10), wherein the drive substrate is a flexible substrate.

(12) The display unit according to any one of (1) to (11), wherein a wiring substrate configured to be electrically connected with the drive device is provided at the circuit forming region on the drive substrate.

(13) The display unit according to any one of (1) to (12), wherein the drive device is an IC.

(14) The display unit according to any one of (1) to (13), wherein the functional film is an optical functional film, a moisture-proof film, or a protective film.

(15) A display unit, comprising:

a drive substrate having a display region and a circuit forming region;

a drive device provided at the circuit forming region on the drive substrate; and

a functional film having a thickness equal to or larger than a thickness of the drive substrate, and provided to cover the display region and to be opposed to a part of the circuit forming region.

(16) The display unit according to (15), wherein the derive device is provided at a non-superposed region that does not overlap with the functional film of the circuit forming region.

(17) The display unit according to (16), wherein the functional film has a notch portion, and the drive device is provided at a position overlapping with the notch portion in planar view.

(18) The display unit according to (15) or (16), wherein the functional film has an aperture, and the drive device is provided at a position overlapping with the aperture in planar view.

(19) An electronic apparatus provided with a display unit, the display unit comprising:

a drive substrate having a display region and a circuit forming region;

a drive device provided at the circuit forming region on the drive substrate;

a functional film provided to cover the display region and to be opposed to a part of the circuit forming region; and

a protective resin layer provided in contact with the drive device.

(20) An electronic apparatus provided with a display unit, the display unit comprising:

a drive substrate having a display region and a circuit forming region;

a drive device provided at the circuit forming region on the drive substrate; and

a functional film having a thickness equal to or larger than a thickness of the drive substrate, and provided to cover the display region, and to be opposed to a part of the circuit forming region.

This application claims the benefit of Japanese Priority Patent Application JP 2014-016028 filed with the Japan patent office on Jan. 30, 2014, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A display unit, comprising:
a drive substrate having a display region and a circuit forming region;
a drive device provided at the circuit forming region on the drive substrate;
a functional film provided to cover the display region and to be opposed to a part of the circuit forming region; and
a protective resin layer provided in contact with the drive device.

2. The display unit according to claim 1, wherein the derive device is provided at a non-superposed region that does not overlap with the functional film of the circuit forming region.

3. The display unit according to claim 1, wherein at least a part of a peripheral region of the drive device is surrounded by the functional film in planar view.

4. The display unit according to claim 3, wherein the protective resin layer is provided over a region surrounded by the functional film.

5. The display unit according to claim 1, wherein a thickness of the functional film is larger than a thickness of the drive substrate.

6. The display unit according to claim 2, wherein the functional film has a notch portion, and the drive device is provided at a position overlapping with the notch portion in planar view.

7. The display unit according to claim 2, wherein the functional film has an aperture, and the drive device is provided at a position overlapping with the aperture in planar view.

8. The display unit according to claim 1, wherein a display layer and an opposite substrate are provided at the display region on the drive substrate, and
the functional film is opposed to the drive substrate with the display layer and the opposite substrate interposed between.

9. The display unit according to claim 8, wherein the display layer includes an electrophoretic type display body.

10. The display unit according to claim 8, wherein the display layer includes an organic EL layer.

11. The display unit according to claim 1, wherein the drive substrate is a flexible substrate.

12. The display unit according to claim 1, wherein a wiring substrate configured to be electrically connected with the drive device is provided at the circuit forming region on the drive substrate.

13. The display unit according to claim 1, wherein the drive device is an IC.

14. The display unit according to claim 1, wherein the functional film is an optical functional film, a moisture-proof film, or a protective film.

15. A display unit, comprising:
a drive substrate having a display region and a circuit forming region;
a drive device provided at the circuit forming region on the drive substrate; and
a functional film having a thickness equal to or larger than a thickness of the drive substrate, and provided to cover the display region and to be opposed to a part of the circuit forming region.

16. The display unit according to claim 15, wherein the derive device is provided at a non-superposed region that does not overlap with the functional film of the circuit forming region.

17. The display unit according to claim 16, wherein the functional film has a notch portion, and the drive device is provided at a position overlapping with the notch portion in planar view.

18. The display unit according to claim 16, wherein the functional film has an aperture, and the drive device is provided at a position overlapping with the aperture in planar view.

19. An electronic apparatus provided with a display unit, the display unit comprising:
a drive substrate having a display region and a circuit forming region;
a drive device provided at the circuit forming region on the drive substrate;
a functional film provided to cover the display region and to be opposed to a part of the circuit forming region; and
a protective resin layer provided in contact with the drive device.

20. An electronic apparatus provided with a display unit, the display unit comprising:
a drive substrate having a display region and a circuit forming region;
a drive device provided at the circuit forming region on the drive substrate; and
a functional film having a thickness equal to or larger than a thickness of the drive substrate, and provided to cover the display region, and to be opposed to a part of the circuit forming region.
